(19) United States
(12) Patent Application Publication
(10) Pub. No.: US 2023/0261013 A1
(43) Pub. Date: Aug. 17, 2023

(54) PHOTOELECTRIC SENSOR

(71) Applicant: Egis Technology Inc., (US)

(72) Inventors: Bruce C. S. Chou, Hsinchu City (TW); Chen-Chang Huang, Hsinchu City (TW); Chen-Chih Fan, Hsinchu City (TW)

(73) Assignee: Egis Technology Inc., Hsinchu City (TW)

(21) Appl. No.: 17/913,820

(22) PCT Filed: Nov. 27, 2020
(86) PCT No.: PCT/CN2020/132403

§ 371 Date: Sep. 22, 2022

Related U.S. Application Data
(60) Provisional application No. 63/010,691, filed on Apr. 16, 2020.

(51) Int. Cl. H01L 27/146

(52) U.S. Cl. CPC H01L 27/1461; H01L 27/14643

(57) ABSTRACT

The invention provides a photoelectric sensor including a substrate and multiple pixel structures. The pixel structures are disposed on the substrate and arranged in an array. Each of the pixel structures includes a transistor and a photodiode. The photodiode includes a first electrode, a photosensitive layer, and a second electrode. The first electrode and the transistor are laterally arranged side by side. A first part of the photosensitive layer is disposed on the first electrode, and a second part of the photosensitive layer extends from the first part to above the transistor. The second electrode is disposed on the photosensitive layer, and is located above the first electrode and the transistor.

### BACKGROUND

### Technical Field

The invention relates to a photoelectric element, in particular to a photoelectric sensor.

### DESCRIPTION OF RELATED ART

A photoelectric sensor generally senses light by a photodiode, and the general structure includes a substrate as well as a photodiode and a transistor disposed on the substrate. In the pixel structure of the thin film transistor (TFT) photoelectric sensor, the thin film transistor and the photodiode are arranged side by side on the substrate.

In order to make the photodiode of the photoelectric sensor (i.e., the photosensitive unit) to obtain more incident light energy, the area of the photodiode needs to be enlarged as much as possible. However, although the photodiode area enlargement can increase the amount of light, it will affect the thin film transistor next to the photodiode. Thin film transistors have their minimum area requirements depending on the manufacturing process. When the size of the photodiode is increased, since the thin film transistor cannot be reduced, the fill factor of the photoelectric sensor cannot be improved, where the fill factor is the ratio of the area of the photodiode divided by the area of the pixel structure of the photoelectric sensor.

In addition, when the photoelectric sensor is applied in the under-screen fingerprint sensor, since the screen will block most of the light, the photosensitive requirements of the photoelectric sensor will be much higher than when it is applied in other occasions. At this point, it is very important to improve the fill factor of the photoelectric sensor.

### SUMMARY

The invention provides a photoelectric sensor that has a high fill factor and may be fabricated by a simpler manufacturing process.

One embodiment of the invention provides a photoelectric sensor including a substrate and multiple pixel structures. The pixel structures are disposed on the substrate and arranged in an array. Each of the pixel structures includes a transistor and a photodiode. The photodiode includes a first electrode, a photosensitive layer, and a second electrode. The first electrode is laterally arranged side by side with the transistor. A first part of the photosensitive layer is disposed on the first electrode, and a second part of the photosensitive layer extends from the first part to above the transistor. The second electrode is disposed on the photosensitive layer, and is located above the first electrode and the transistor.

In the photoelectric sensor of the embodiment of the invention, since the photosensitive layer for photosensitive extends above the transistor, a photosensitive area is increased, so the fill factor of the photoelectric sensor may be effectively improved. In addition, a structure of the photoelectric sensor is suitable for the original simpler manufacturing process, and may be manufactured without requiring a more advanced manufacturing process for the innovation of the structure.

### BRIEF DESCRIPTION OF THE DRAWING

FIG. 1 is a schematic top view of a photoelectric sensor according to an embodiment of the invention.

FIG. 2 is a schematic cross-sectional view of pixel structures in FIG. 1.

FIG. 3A is a schematic view of distribution of a photosensitive area relative to an overall area of pixel in pixel structures in which a thin film transistor and a photodiode are arranged side by side.

FIG. 3B is a schematic view of distribution of a photosensitive area relative to an overall area of pixel in the pixel structures of FIG. 2.

### DESCRIPTION OF THE EMBODIMENTS

Reference will now be made in detail to the exemplary embodiments of the invention, examples of which are illustrated in the drawings. Wherever possible, the same reference numerals are used in the drawings and the description to refer to the same or similar parts.

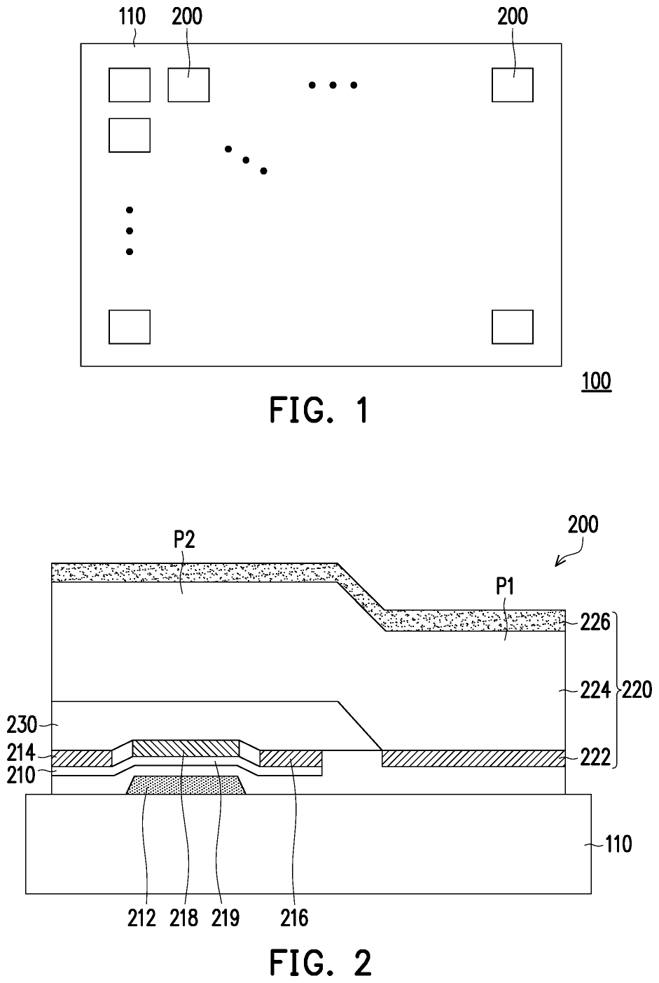

FIG. 1 is a schematic top view of a photoelectric sensor according to an embodiment of the invention, and FIG. 2 is a schematic cross-sectional view of pixel structures in FIG. 1. Referring to FIG. 1 and FIG. 2, a photoelectric sensor 100 according to this embodiment includes a substrate 110 and multiple pixel structures 200, and the pixel structures 200 are disposed on the substrate 110 and arranged in an array. According to this embodiment, the photoelectric sensor 100 is, for example, an image sensor, and the pixel structures 200 respectively form multiple pixels of the image sensor. According to this embodiment, the substrate 110 is a glass substrate, a sapphire substrate or a semiconductor substrate. The semiconductor substrate is, for example, a silicon substrate, a gallium nitride substrate, a gallium arsenide substrate or a substrate made of other semiconductor materials.

Each of the pixel structures 200 includes a transistor 210 and a photodiode 220. The photodiode 220 includes a first electrode 222, a photosensitive layer 224, and a second electrode 226. The first electrode 222 and the transistor 210 are laterally arranged side by side. A first part P1 of the photosensitive layer 224 is disposed on the first electrode 222, and a second part P2 of the photosensitive layer 224 extends from the first part P1 to above the transistor 210. The second electrode 226 is disposed on the photosensitive layer 224 and above the first electrode 222 and the transistor 210. According to this embodiment, the first electrode 222 is in contact with the first part P1 of the photosensitive layer 224, and the second electrode 226 is in contact with both the first part P1 and the second part P2 of the photosensitive layer 224 to form a photodiode structure.

According to this embodiment, the photosensitive layer 224 is an intrinsic semiconductor layer, the first electrode 222 is a P-type doped semiconductor layer, and the second electrode 226 is an N-type doped semiconductor layer. For example, the first electrode 222 is a heavily doped p-type polysilicon layer, the photosensitive layer 224 is an intrinsic silicon amorphous silicon layer, and the second electrode is a heavily doped n-type amorphous silicon layer. However, according to another embodiment, the first electrode 222 may also be an N-type doped semiconductor layer, and the second electrode 226 may be a P-type doped semiconductor layer. In addition, according to this embodiment, the transistor 210 is a thin film transistor.

In the photoelectric sensor 100 of this embodiment, since the second part P2 of the photosensitive layer 224 for photosensitive extends above the transistor 210, a photosensitive area is increased, so a fill factor of the photoelectric sensor 100 may be effectively improved. In addition, a structure of the photoelectric sensor 100 is suitable for the original simpler manufacturing process (e.g., a semiconductor process), and may be manufactured without requiring a more advanced manufacturing process (e.g., a more advanced semiconductor process) for the innovation of the structure. Therefore, the manufacturing cost of the photoelectric sensor 100 may be effectively controlled.

According to this embodiment, the second part P2 of the photosensitive layer 224 covers the transistor 210, and the second electrode 226 covers the transistor 210. In addition, the second electrode 226 also covers the first electrode 222. The each of the pixel structures 200 further includes an insulating layer 230 disposed between the second part P2 of the photosensitive layer 224 and the transistor 210.

According to this embodiment, the transistor 210 has a control end 212, a first end 214, and a second end 216. The control end 212 is, for example, a gate. The first end 214 and the second end 216 are, for example, a source and a drain, respectively, or a drain and a source, respectively. According to this embodiment, the second end 216 and the first electrode 222 are formed by the same semiconductor layer, or the first end 214, the second end 216, and the first electrode 222 are formed by the same semiconductor layer. That is, the first end 214, the second end 216, and the first electrode 222 may be defined by the same mask process. In this way, the processes of the transistor 210 and the photodiode 220 may still be effectively integrated to reduce the number of required masks, thereby effectively reducing the manufacturing cost of the photoelectric sensor 100.

In addition, according to this embodiment, the transistor 210 may further include a light shielding layer 218 disposed above the control end 212 to shield light from above the light shielding layer 218 and suppress the amount of light irradiated on a channel layer 219 electrically connected to the first end 214 and the second end 216. Thus, the operation of the transistor 210 is not disturbed by the light from the outside.

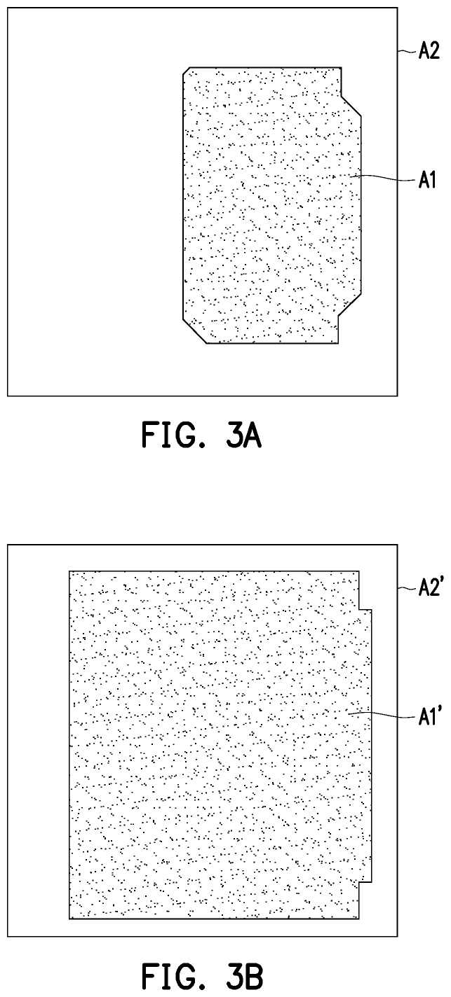

FIG. 3A is a schematic view of distribution of a photosensitive area relative to an overall area of pixel in pixel structures in which a thin film transistor and a photodiode are arranged side by side. FIG. 3B is a schematic view of distribution of a photosensitive area relative to an overall area of pixel in the pixel structures of FIG. 2. Referring to FIG. 3A first, in the pixel structures in which the thin film transistor and the photodiode are arranged side by side, a ratio (i.e., a fill factor) of a photosensitive area A1 formed by the photosensitive layer of the photodiode to an overall area A2 of the pixel structures is generally about 33%. At this time, the photosensitive area A1 is, for example, about 1,600 μm², and the overall area A2 of the pixel structures is about 4,900 μm², for example. Referring to FIG. 2 and FIG. 3B again, in the pixel structures 200 of the this embodiment, since the photosensitive layer 224 extends above the transistor 210, a ratio (i.e., a fill factor) of a photosensitive area A1′ formed by the photosensitive layer 224 of the photodiode 220 to an overall area A2′ of the pixel structures 200 is increased to 69%. At this time, the photosensitive area A1′ is, for example, 4,410 μm², and the overall area A2′ of the pixel structures 200 is, for example, 6,400 μm. That is, the fill factor of the photoelectric sensor 100 of this embodiment is greatly improved compared to the photoelectric sensor using the pixel structures in which the thin film transistor and the photodiode are arranged side by side.

To sum up, in the photoelectric sensor of the embodiment of the invention, since the photosensitive layer for photosensitive extends above the transistor, a photosensitive area is increased, so the fill factor of the photoelectric sensor may be effectively improved. In addition, a structure of the photoelectric sensor is suitable for the original simpler manufacturing process, and may be manufactured without requiring a more advanced manufacturing process for the innovation of the structure.

Finally, it should be noted that the above embodiments are only used to illustrate, but not to limit, the technical solutions of the invention. Although the invention has been described in detail with reference to the above embodiments, persons skilled in the art should understand that the technical solutions described in the above embodiments can still be modified or some or all of the technical features thereof can be equivalently replaced. However, the modifications or replacements do not cause the essence of the corresponding technical solutions to deviate from the scope of the technical solutions of the embodiments of the invention.

What is claimed is:

1. A photoelectric sensor, comprising:
a substrate; and
a plurality of pixel structures disposed on the substrate and arranged in an array, wherein each of the pixel structures comprises:
a transistor; and
a photodiode, comprising:
a first electrode laterally arranged side by side with the transistor;
a photosensitive layer, wherein a first part of the photosensitive layer is disposed on the first electrode, and a second part of the photosensitive layer extends from the first part to above the transistor; and
a second electrode disposed on the photosensitive layer, and located above the first electrode and the transistor.

2. The photoelectric sensor according to claim 1, wherein the photosensitive layer and the second electrode cover the transistor.

3. The photoelectric sensor according to claim 2, wherein the second electrode also covers the first electrode.

4. The photoelectric sensor according to claim 1, wherein the each of the pixel structures further comprises an insulating layer disposed between the second part of the photosensitive layer and the transistor.

5. The photoelectric sensor according to claim 1, wherein the photosensitive layer is an intrinsic semiconductor layer, the first electrode is a P-type doped semiconductor layer, and the second electrode is an N-type doped semiconductor layer.

6. The photoelectric sensor according to claim 1, wherein the photosensitive layer is an intrinsic semiconductor layer, the first electrode is an N-type doped semiconductor layer, and the second electrode is a P-type doped semiconductor layer.

7. The photoelectric sensor according to claim 1, wherein the transistor is a thin film transistor.

8. The photoelectric sensor according to claim 7, wherein the transistor has a control end, a first end, and a second end, and the second end and the first electrode are formed by the same semiconductor layer.

9. The photoelectric sensor according to claim 1, wherein the first electrode is a heavily doped p-type polysilicon layer, the photosensitive layer is an intrinsic amorphous silicon layer, and the second electrode is a heavily doped n-type amorphous silicon layer.

10. The photoelectric sensor according to claim 1, wherein the substrate is a glass substrate, a sapphire substrate or a semiconductor substrate.
